(19) United States
(12) Patent Application Publication
(10) Pub. No.: US 2026/0290456 A1
(43) Pub. Date: Sep. 24, 2026

(54) SEMICONDUCTOR MEMORY DEVICE

(71) Applicant: Kioxia Corporation, Tokyo (JP)

(72) Inventor: Hiroki DATE, Chigasaki (JP)

(73) Assignee: Kioxia Corporation, Tokyo (JP)

(21) Appl. No.: 19/292,454

(22) Filed: Aug. 6, 2025

(30) Foreign Application Priority Data
Mar. 21, 2025 (JP) 2025-047290

(51) Int. Cl. G11C 16/04; G11C 16/08; G11C 16/12; G11C 16/26; G11C 16/30; H10B 41/10; H10B 41/27; H10B 41/35; H10B 43/10; H10B 43/27; H10B 43/35

(52) U.S. Cl. CPC G11C 16/0483; G11C 16/08; G11C 16/12; G11C 16/30; H10B 41/10; H10B 41/27; H10B 41/35; H10B 43/10; H10B 43/27; H10B 43/35; G11C 16/26

(57) ABSTRACT

A semiconductor memory device includes a memory cell array including memory cells and word lines; a first booster circuit configured to boost an input voltage to generate a first voltage; a second booster circuit configured to boost the input voltage to generate a second voltage higher than the first voltage; a first regulator configured to adjust the first voltage to output a third voltage; a second regulator configured to adjust the second voltage to output a fourth voltage; a switch circuit configured to receive the first voltage and the second voltage and output one of the first voltage or the second voltage; and a row decoder configured to apply a voltage to the word lines. The switch circuit is configured to switch an output from the first voltage to the second voltage in response to the first voltage being boosted to a target voltage by the first booster circuit.

### CROSS-REFERENCE TO RELATED APPLICATION

This application is based upon and claims the benefit of priority from Japanese Patent Application No. 2025-047290, filed Mar. 21, 2025, the entire contents of which are incorporated herein by reference.

### FIELD

Embodiments described herein relate generally to a semiconductor memory device.

### BACKGROUND

A NAND flash memory is known as a semiconductor memory device capable of storing data in a non-volatile manner.

### DESCRIPTION OF THE DRAWINGS

FIG. 1 is a block diagram showing a circuit configuration of a semiconductor memory device according to a first embodiment.

FIG. 2 is a circuit diagram of a block in a memory cell array according to the first embodiment.

FIG. 3 is a diagram showing a relationship between a possible threshold voltage distribution of a memory cell transistor and data according to the first embodiment.

FIG. 4 is a diagram showing a planar layout of the memory cell array according to the first embodiment.

FIG. 5 is a diagram showing a cross-sectional structure of a memory region in the memory cell array according to the first embodiment.

FIG. 6 is a timing chart showing a read operation of a lower page in the semiconductor memory device according to the first embodiment.

FIG. 7 is a block diagram showing a configuration of a word line voltage supply circuit of the semiconductor memory device according to the first embodiment.

FIG. 8 is a circuit diagram showing a basic configuration of a charge pump provided in the word line voltage supply circuit according to the first embodiment.

FIG. 9 is a diagram showing voltages of a booster circuit and a word line in the read operation according to the first embodiment.

FIG. 10 is a block diagram showing a configuration of a word line voltage supply circuit of a semiconductor memory device according to a second embodiment.

FIG. 11 is a diagram showing voltages of a booster circuit and a word line in the read operation according to the second embodiment.

### DETAILED DESCRIPTION

Embodiments provide a semiconductor memory device that can improve reliability of an operation.

In general, according to one embodiment, a semiconductor memory device includes a memory cell array including a plurality of memory cells and a plurality of word lines; a first booster circuit configured to boost an input voltage to generate a first voltage; a second booster circuit configured to boost the input voltage to generate a second voltage higher than the first voltage; a first regulator configured to adjust the first voltage to output a third voltage; a second regulator configured to adjust the second voltage to output a fourth voltage; a switch circuit configured to receive the first voltage and the second voltage and output one of the first voltage or the second voltage; and a row decoder configured to apply a voltage to the plurality of word lines. The switch circuit is configured to switch an output from the first voltage to the second voltage in response to the first voltage being boosted to a target voltage by the first booster circuit.

In the following description, elements having the same function and configuration are given by common reference numeral. In addition, embodiments described below are examples of devices or methods for embodying the technical idea of the embodiment, and a material, a shape, a structure, and a disposition of components do not specify those which are described below.

In addition, the drawings referred to below are schematic or conceptual. The dimensions, ratios, and the like in each drawing do not necessarily match the actual ones. In some drawings showing the structure, an XYZ orthogonal coordinate system is used. An X direction extends along an X axis. A Y direction extends along a Y axis. A Z direction extends along a Z axis. The X direction and the Y direction are directions orthogonal to each other. The Z direction is orthogonal to each of the X direction and the Y direction and corresponds to a vertical direction with respect to a surface of a semiconductor substrate. In addition, a side having larger coordinates on the X axis (X direction), Y axis (Y direction), or Z axis (Z direction) may be referred to as a positive direction, and a side having smaller coordinates may be referred to as a negative direction. A positive direction of the Z axis may be referred to as an upper side, and a negative direction of the Z axis may be referred to as a lower side. A positive direction of the X axis or the Y axis may be referred to as a right side, and a negative direction may be referred to as a left side. In addition, hatching is appropriately added to the plan view to make the drawing easy to see. The hatching added to the plan view is not necessarily related to the material or property of the element to which the hatching is added. In each of the plan view and the cross-sectional view, wiring, contact plugs, interlayer insulating films, and the like are omitted as appropriate in order to make the drawing easy to see.

In the following, a semiconductor memory device according to an embodiment will be described. As a semiconductor memory device, a three-dimensional stacked NAND flash memory in which memory cell transistors are three-dimensionally stacked above a semiconductor substrate is taken as an example. The NAND flash memory is a semiconductor memory that can store data in a non-volatile manner.

For example, in the read operation in the semiconductor memory device, a read voltage VCGRV is applied to the selected word line, and a voltage VREAD is applied to the non-select word line. For example, one word line corresponds to the selected word line, and several hundred word lines correspond to the non-select word lines. In recent years, the number of word lines increases, and the demand for improved performance continues to grow. Therefore, in the read operation, the current at the time of the boost (or at the time of charging) the non-select word line may increase, and it may be difficult to reduce the peak current.

Therefore, in the embodiment, in the read operation, the peak current occurring in the circuit that supplies a voltage to the word line is reduced, and a problem caused by the occurrence of the peak current is prevented to improve the reliability of the semiconductor memory device.

### 1. First Embodiment

A semiconductor memory device of a first embodiment will be described.

### 1.1. Circuit Configuration of Semiconductor Memory Device

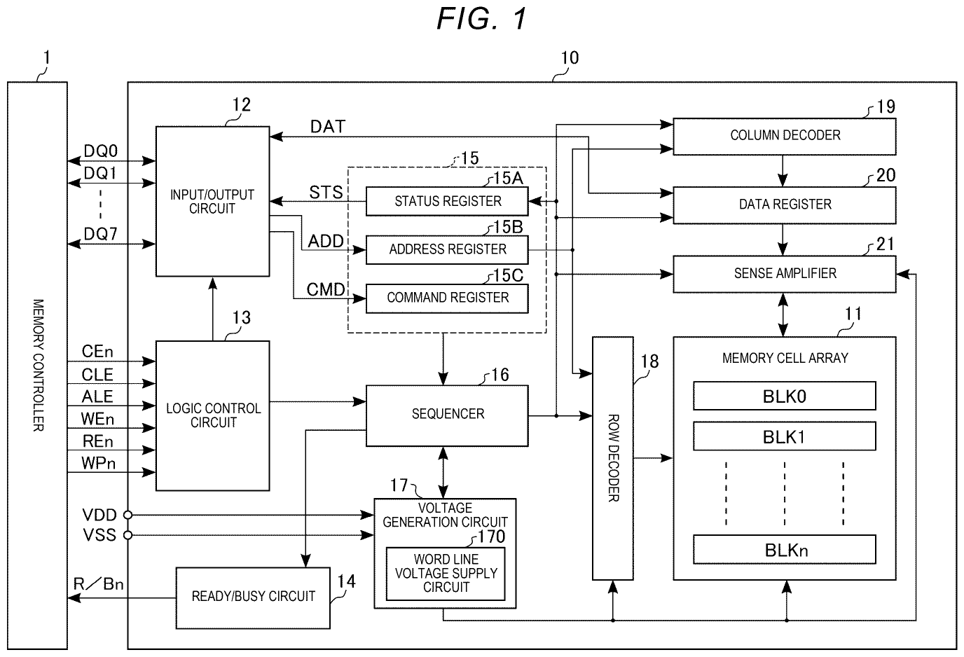

First, a circuit configuration of a semiconductor memory device of the first embodiment will be described. FIG. 1 is a block diagram showing the circuit configuration of the semiconductor memory device of the first embodiment.

The semiconductor memory device 10 of the first embodiment includes, for example, a NAND flash memory, and stores data in a non-volatile manner. A memory controller 1 is connected to the semiconductor memory device 10 via a NAND bus. The semiconductor memory device 10 is controlled by the memory controller 1.

The semiconductor memory device 10 includes a memory cell array 11, an input/output circuit 12, a logic control circuit 13, a ready/busy circuit 14, a register group 15, a sequencer (or control circuit) 16, a voltage generation circuit 17, a row decoder 18, and a column decoder 19, a data register 20, and a sense amplifier 21. The register group 15 includes a status register 15A, an address register 15B, and a command register 15C.

The memory cell array 11 includes one or a plurality of blocks BLK0, BLK1, BLK2, . . . , and BLKn (n is an integer of 0 or more). Each of the plurality of blocks BLK0 to BLKn includes a plurality of memory cell transistors (hereinafter, also referred to as memory cells) correlated with rows and columns. The memory cell transistors are non-volatile memory cells that are electrically erasable and programmable. The memory cell array 11 includes a plurality of word lines, a plurality of bit lines, and a source line in order to apply a voltage to the memory cell transistor. The specific configuration of the block BLKn will be described later.

The input/output circuit 12 and the logic control circuit 13 are connected to the memory controller 1 via an input/output terminal (or the NAND bus). The input/output circuit 12 performs communication with I/O signals DQ (for example, DQ0, DQ1, DQ2, . . . , and DQ7) to and from the memory controller 1 via input/output terminals. The I/O signal DQ communicates commands, addresses, data, and the like.

The logic control circuit 13 receives an external control signal from the memory controller 1 via the input/output terminal (or the NAND bus). The external control signal includes, for example, a chip enable signal CEn, a command latch enable signal CLE, an address latch enable signal ALE, a write enable signal WEn, a read enable signal REn, and a write protect signal WPn. An “n” added to the signal name indicates that the signal is active low.

The chip enable signal CEn enables selection of the semiconductor memory device 10 when a plurality of semiconductor memory devices 10 are mounted, and is asserted when the semiconductor memory device 10 is selected. The command latch enable signal CLE makes it possible to latch a command transmitted as a signal DQ to the command register 15C. The address latch enable signal ALE makes it possible to latch the address transmitted as a signal DQ to the address register 15B. The write enable signal WEn makes it possible to store the data transmitted as a signal DQ in the input/output circuit 12. The read enable signal REn makes it possible to output the data read from the memory cell array 11 as a signal DQ. The write protect signal WPn is asserted when prohibiting the write operation and the erase operation for the semiconductor memory device 10.

The ready/busy circuit 14 generates a ready/busy signal R/Bn according to the control from the sequencer 16. The ready/busy signal R/Bn indicates whether the semiconductor memory device 10 is in the ready state or the busy state. The ready state indicates that the semiconductor memory device 10 is in a state where an instruction from the memory controller 1 can be accepted. The busy state indicates that the semiconductor memory device 10 is in a state where an instruction from the memory controller 1 cannot be accepted. By receiving the ready/busy signal R/Bn from the semiconductor memory device 10, the memory controller 1 can know whether the semiconductor memory device 10 is in the ready state or the busy state.

The status register 15A stores status information STS necessary for the operation of the semiconductor memory device 10. The status register 15A transfers the status information STS to the input/output circuit 12 according to the instruction of the sequencer 16.

The address register 15B stores the address ADD transferred from the input/output circuit 12. The address ADD includes a row address and a column address. The row address includes, for example, a block address that designates the block BLKn to be operated, and a page address that designates a word line WL to be operated in the designated block.

The command register 15C stores a command CMD transferred from the input/output circuit 12. The command CMD includes, for example, a write command for ordering a write operation to the sequencer 16, a read command for ordering a read operation, an erase command for ordering an erase operation, and the like.

For example, a static random access memory (SRAM) is used for the status register 15A, the address register 15B, and the command register 15C.

The sequencer 16 receives the command from the command register 15C and controls the semiconductor memory device 10 in an integrated manner according to a sequence based on this command.

The sequencer 16 controls the voltage generation circuit 17, the row decoder 18, the column decoder 19, the data register 20, the sense amplifier 21, and the like to execute the write operation, the read operation, and the erase operation. Specifically, the sequencer 16 controls the voltage generation circuit 17, the row decoder 18, the data register 20, and the sense amplifier 21 based on the write command received from the command register 15C to write data into a plurality of memory cell transistors designated by the address ADD. The sequencer 16 also controls the voltage generation circuit 17, the row decoder 18, the column decoder 19, the data register 20, and the sense amplifier 21 based on the read command received from the command register 15C to read data from the plurality of memory cell transistors designated by the address ADD. The sequencer 16 also controls the voltage generation circuit 17, the row decoder 18, the column decoder 19, the data register 20, and the sense amplifier 21 based on the erase command received from the command register 15C to erase the data stored in the block designated by the address ADD. A circuit including the column decoder 19, the data register 20, and the like is referred to as a column control circuit.

The voltage generation circuit 17 receives a power supply voltage VCC and a ground voltage VSS from an outside of the semiconductor memory device 10 via a power supply terminal. The power supply voltage VCC is an external voltage supplied from the outside of the semiconductor memory device 10. The ground voltage VSS is an external voltage supplied from the outside of the semiconductor memory device 10, and is, for example, 0 V.

The voltage generation circuit 17 uses the power supply voltage VCC to generate a plurality of voltages necessary for the write operation, the read operation, and the erase operation. The voltage generation circuit 17 supplies the generated voltage to the memory cell array 11, the row decoder 18, the sense amplifier 21, and the like. The voltage generation circuit 17 includes a word line voltage supply circuit 170. The word line voltage supply circuit 170 will be described in detail later.

The row decoder 18 receives a row address from the address register 15B and decodes the row address. The row decoder 18 selects one of a plurality of blocks based on the decoding result of the row address, and further selects the word line WL in the selected block BLKn. Furthermore, the row decoder 18 transfers the plurality of voltages supplied from the voltage generation circuit 17 to the selected block BLKn.

The column decoder 19 receives a column address from the address register 15B and decodes the column address. The column decoder 19 selects a latch circuit in the data register 20 based on the decoding result of the column address.

The data register 20 includes a plurality of latch circuits. The latch circuit temporarily stores write data or read data.

The sense amplifier 21 senses and amplifies the data read from the memory cell transistors into the bit line during the data read operation. Furthermore, the sense amplifier 21 temporarily stores read data DAT read from the memory cell transistors, and transfers the stored read data DAT to the data register 20. In addition, the sense amplifier 21 temporarily stores write data DAT transferred from the input/output circuit 12 via the data register 20 during the data write operation. Furthermore, the sense amplifier 21 transfers the write data DAT to the bit line.

Next, a circuit configuration of the memory cell array 11 in the semiconductor memory device 10 according to the first embodiment will be described. As described above, the memory cell array 11 has the plurality of blocks BLK0 to BLKn. In the following, the circuit configuration of the block BLKn will be described.

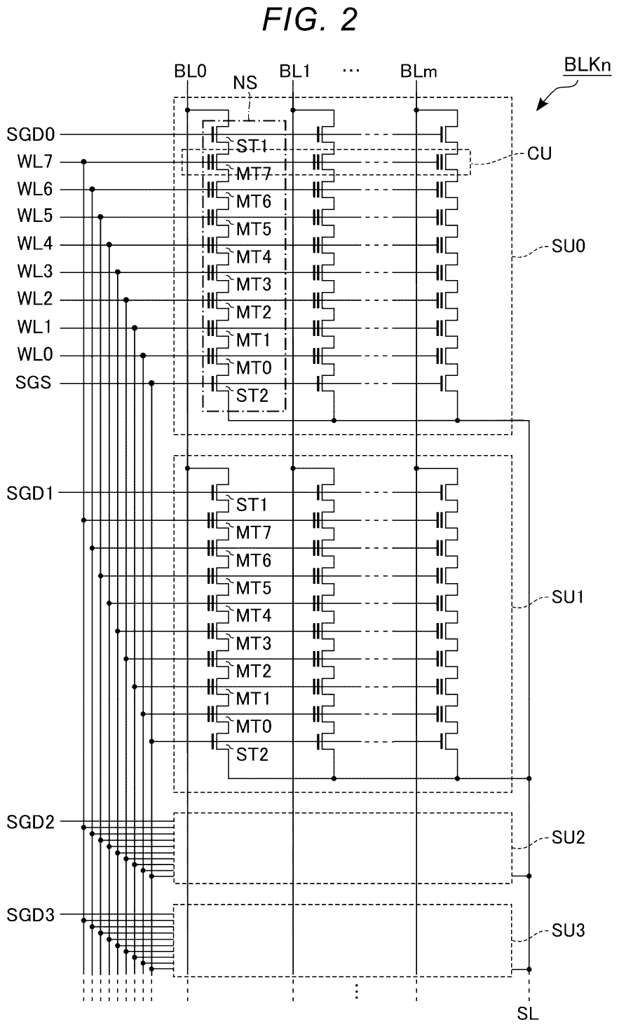

FIG. 2 is a circuit diagram of the block BLKn in the memory cell array 11. The block BLKn includes, for example, a plurality of string units SU0, SU1, SU2, and SU3. Hereinafter, the term “string unit SU” refers to each of the string units SU0 to SU3. The string unit SU includes a plurality of NAND strings (or memory strings) NS.

Here, for the sake of simplicity, an example is shown in which the NAND string NS includes, for example, eight memory cell transistors MT0, MT1, MT2, . . . , and MT7, and two select transistors ST1 and ST2. Hereinafter, the term “memory cell transistor MT” refers to each of the memory cell transistors MT0 to MT7.

The memory cell transistor MT includes a control gate and a charge storage layer, and stores data in a non-volatile manner. The memory cell transistors MT0 to MT7 are connected in series between a source of the select transistor ST1 and a drain of the select transistor ST2. The memory cell transistor MT can store 1-bit data or 2 or more bits of data.

Gates of a plurality of select transistors ST1 provided in the string unit SU0 are connected to a select gate line SGD0. Similarly, the gates of the select transistor ST1 of the string units SU1 to SU3 are connected to the select gate lines SGD1 to SGD3, respectively. Each of the select gate lines SGD0 to SGD3 is independently controlled by the row decoder 18.

Gates of a plurality of select transistors ST2 provided in the string unit SU0 are connected to a select gate line SGS. Similarly, the gate of each select transistor ST2 of the string units SU1 to SU3 is connected to the select gate line SGS. In some cases, individual select gate lines SGS may be connected to the gates of the select transistors ST2 of the string units SU0 to SU3, respectively. The select transistors ST1 and ST2 are used to select the string unit SU in various operations.

The control gates of the memory cell transistors MT0 to MT7 provided in the block BLKn are connected to the word lines WL0 to WL7, respectively. Each of the word lines WL0 to WL7 is independently controlled by the row decoder 18.

Each of the bit lines BL0, BL1, BL2, . . . , and BLm (m is a natural number of 0 or more) is connected to the plurality of blocks BLK0 to BLKn and is connected to one NAND string NS in the string unit SU provided in the block BLKn. That is, each of the bit lines BL0 to BLm is connected to the drains of the select transistors ST1 of the plurality of NAND strings NS in the same column among the NAND strings NS arranged in a matrix configuration in the block BLKn. In addition, the source line SL is connected to the plurality of blocks BLK0 to BLKn. That is, the source line SL is connected to the sources of the plurality of select transistors ST2 provided in the block BLKn.

In short, the string unit SU includes a plurality of NAND strings NS connected to different bit lines BL and connected to the same select gate line SGD. In addition, the block BLKn includes a plurality of string units SU having a common word line WL. Furthermore, the memory cell array 11 includes the plurality of blocks BLK0 to BLKn having a common bit line BL.

The block BLKn is, for example, a unit for erasing data. That is, the data stored in the memory cell transistor MT provided in the block BLKn is collectively erased. The data in the plurality of blocks is sequentially erased for each block. In addition, the data in the plurality of blocks is erased at the same time in parallel. The data may be erased in units of string unit SU, or may be erased in units of less than the string unit SU.

The plurality of memory cell transistors MT sharing the word line WL in one string unit SU are referred to as a cell unit CU. A collection of 1-bit data stored in each of the plurality of memory cell transistors MT provided in the cell unit CU is referred to as a page. The storage capacity of the cell unit CU changes depending on the number of bits of data stored in the memory cell transistor MT. For example, the cell unit CU stores 1 piece of page data when each memory cell transistor MT stores 1-bit data, stores 2 pieces of page data when storing 2-bit data, and stores 3 pieces of page data when storing 3-bit data, respectively.

The write operation and the read operation for the cell unit CU are performed in units of pages. In other words, the read operation and the write operation are collectively performed on a plurality of memory cell transistors MT connected to one word line WL arranged in one string unit SU.

The number of string units provided in the block BLKn is not limited to SU0 to SU3, and can be set in any manner. In addition, the number of NAND strings NS provided in the string unit SU, the number of memory cell transistors provided in the NAND string NS, and the number of select transistors can be set in any manner. Furthermore, the memory cell transistor MT may be a metal-oxide-nitride-oxide-silicon (MONOS) type using an insulating film as a charge storage layer, or a floating gate (FG) type using a conductive layer as a charge storage layer.

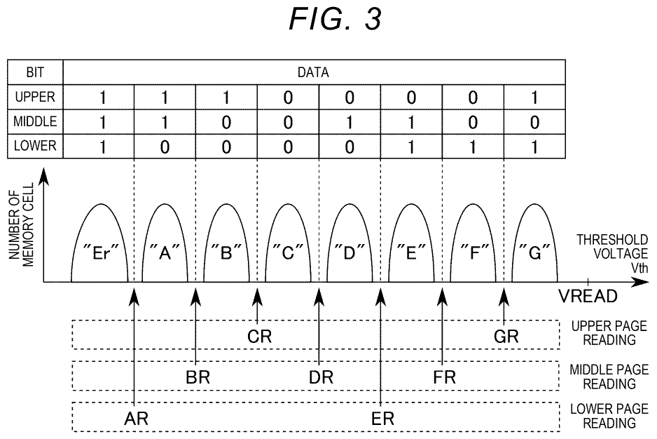

Next, a relationship between a possible threshold voltage distribution of the memory cell transistor MT and data will be described. FIG. 3 is a diagram showing the relationship between the possible threshold voltage distribution of the memory cell transistor MT and data.

Here, an example in which a triple-level cell (TLC) method capable of storing 3-bit data in one memory cell transistor MT is applied is shown as a storage method of the memory cell transistor MT. In the present embodiment, a single-level cell (SLC) method capable of storing 1-bit data in one memory cell transistor MT, a multi-level cell (MLC) method capable of storing 2-bit data in one memory cell transistor MT, a quad-level cell (QLC) method capable of storing 4-bit data in one memory cell transistor MT, and the like may also be applied when other storage methods are used.

The 3-bit data that can be stored in the memory cell transistor MT is defined by a lower bit, a middle bit, and an upper bit. When the memory cell transistor MT stores 3 bits, the memory cell transistor MT may take any one of eight states corresponding to a plurality of threshold voltages. The eight states are referred to as states “Er”, “A”, “B”, “C”, “D”, “E”, “F”, and “G” in order from the lowest. The plurality of memory cell transistors MT belonging to each of the states “Er”, “A”, “B”, “C”, “D”, “E”, “F”, and “G” form a distribution of threshold voltage as shown in FIG. 3.

The states “Er”, “A”, “B”, “C”, “D”, “E”, “F”, and “G” are, for example, data “111”, “110”, “100”, “000”, “010”, “011”, “001”, “101” are assigned, respectively. The arrangement of the bits is “ZYX”, where the lower bits “X”, the middle bits “Y”, and the upper bits “Z” are used. The assignment of the threshold voltage distribution and the data can be freely set.

In order to read the data stored in the memory cell transistor MT, which is the read target, a state to which the threshold voltage of the memory cell transistor MT belongs is determined. Read voltages AR, BR, CR, DR, ER, FR, and GR are used to determine the state. In the following, the voltage applied to the word line WL to which the memory cell transistor MT, which is the read target, is connected for determining the threshold voltage, including the read voltages AR, BR, CR, DR, ER, FR, and GR, may be referred to as a read voltage VCGRV.

The voltage VREAD is a voltage applied to the word line WL connected to the memory cell transistor MT of the cell unit CU which is a non-read target. The voltage VREAD is higher than the threshold voltage of the memory cell transistor MT in any state. Therefore, the memory cell transistor MT to which the voltage VREAD is applied to the control gate is turned on regardless of the data to be stored.

As described above, each memory cell transistor MT is set to any of the eight states and can store 3-bit data. In addition, writing and reading are performed in page units in one cell unit CU.

When the memory cell transistor MT stores 3-bit data, the lower bit, the middle bit, and the upper bit are assigned to the three pages in one cell unit CU, respectively. A page written by one write operation or a page read by one read operation for the lower bit, middle bit, and upper bit, that is, a set of lower bits, a set of middle bits, and a set of upper bits, which are stored by the cell unit CU, are referred to as a lower page, a middle page, and an upper page, respectively.

When the above data allocation is applied, the lower page is determined by a read operation using the read voltages AR and ER. The middle page is determined by a read operation using the read voltages BR, DR, and FR. The upper page is determined by a read operation using the read voltage CR and GR.

### 1.2. Structure of Semiconductor Memory Device

The structure of the semiconductor memory device 10 according to the first embodiment will be described.

### 1.2.1. Planar Layout of Semiconductor Memory Device

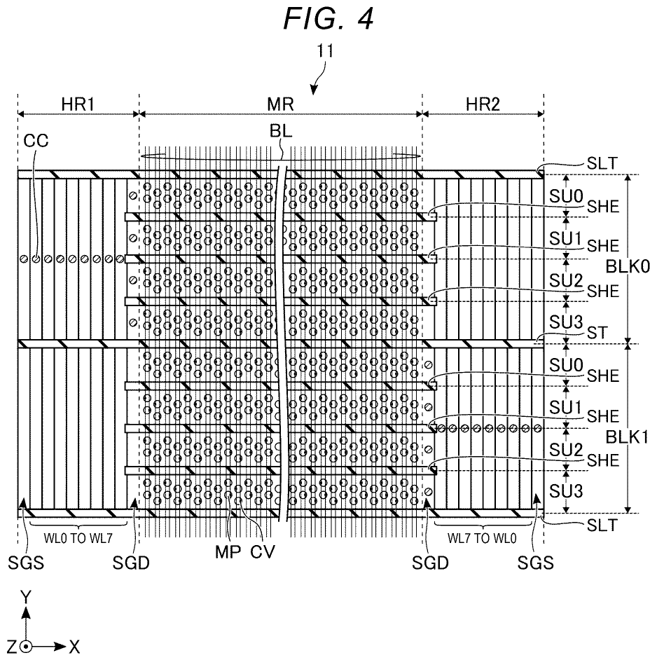

Referring to FIG. 4, an example of a planar layout in the memory cell array 11 of the semiconductor memory device 10 according to the first embodiment will be described. FIG. 4 is a diagram showing a planar layout of the memory cell array 11 of the semiconductor memory device 10. FIG. 4 shows regions corresponding to the blocks BLK0 and BLK1.

As shown in FIG. 4, the semiconductor memory device 10 includes a plurality of slits SLT and SHE, a plurality of memory pillars MP, a plurality of bit lines BL, and a plurality of contacts CC and CV.

The plurality of slits SLT and SHE are arranged in the Y direction. For example, three slits SHE are arranged between the slit SLT and the other slit SLT. Each of the slits SLT and SHE extends along the X direction. Each slit SLT crosses the memory region MR and extraction regions (or step region) HR1 and HR2. Each slit SHE crosses the memory region MR and the select gate lines SGD in the extraction regions HR1 and HR2. That is, each of the slits SLT or SHE divides and insulates between wiring layers (or conductive layers) adjacent to each other via the slit SLT or SHE. Specifically, each slit SLT divides and insulates a plurality of wiring layers corresponding to the word lines WL0 to WL7 and the select gate lines SGD and SGS, respectively. Each of the slits SHE divides and insulates a plurality of wiring layers corresponding to the word lines WL0 to WL7 and the select gate lines SGD, respectively.

Each of the memory pillars MP functions as one NAND string NS, for example. The plurality of memory pillars MP are arranged in a staggered shape in, for example, four rows in a region between the adjacent slits SLT or SHE in the memory region MR. In this example, each of the regions separated by the slits SLT or SHE corresponds to one string unit SU. The number and disposition of the memory pillars MP between the adjacent slits SLT or SHE may be changed as appropriate.

The plurality of bit lines BL are arranged in the X direction. Each bit line BL extends in the Y direction. Each bit line BL overlaps with at least one memory pillar MP for each string unit SU. In this example, two bit lines BL overlap with one memory pillar MP. The contacts CV are provided between one bit line BL among the plurality of bit lines BL overlapping with the memory pillar MP and the memory pillar MP. Each memory pillar MP is connected to an associated bit line BL via the contact CV.

In each of the extraction regions HR1 and HR2, the select gate line SGS, the word lines WL0 to WL7, and the select gate line SGD each have a portion that does not overlap with the upper wiring layer (or the conductive layer). The shape of the portion that does not overlap with the upper wiring layer is referred to as a terrace, a step, a rimstone, and the like. Hereinafter, in the present specification, the portion that does not overlap with the upper wiring layer is referred to as a terrace portion. Specifically, the terrace portions are respectively provided between the select gate line SGS and the word line WL0, between the word line WL0 and the word line WL1, between the word line WL1 and the word line WL2, between the word line WL2 and the word line WL3, between the word line WL3 and the word line WL4, between the word line WL4 and the word line WL5, between the word line WL5 and the word line WL6, between the word line WL6 and the word line WL7, and between the word line WL7 and the select gate line SGD.

Each of a plurality of contacts CC is used for connection between each of the word lines WL0 to WL7 and the select gate lines SGS and SGD, and the row decoder 18. In addition, each contact CC is disposed on the terrace portion of each of the word lines WL0 to WL7 and the select gate lines SGS and SGD. Here, an example in which the contacts CC on the terrace portions of the word lines WL0 to WL7 and the select gate line SGS are arranged in a row in the X direction is shown, but the contacts CC may be disposed to be shifted from each other in the Y direction.

The contact CC associated with the block BLK0 is disposed in the extraction region HR1, for example, and the contact CC associated with the block BLK1 is disposed in the extraction region HR2. In other words, for example, an even-numbered block BLK is connected to the row decoder 18 via the contact CC in the extraction region HR1. An odd-numbered block BLK is connected to the row decoder 18 via the contact CC in the extraction region HR2.

In the planar layout of the semiconductor memory device 10, the memory regions MR, the extraction regions HR1 and HR2 described above are repeatedly arranged in the Y direction. The disposition of the contacts CC with respect to each block BLK is not limited to the layout described above. For example, when one of the extraction regions HR is omitted, the contacts CC corresponding to each block BLK are collectively disposed in the extraction region HR on one side in contact with the memory region MR. In addition, the contacts CC may be disposed on both sides of the extraction regions HR1 and HR2, and a voltage may be applied from both sides of each block BLK. The extraction region HR may be disposed to be interposed between portions of the memory region MR.

### 1.2.2. Cross-Sectional Structure of Semiconductor Memory Device

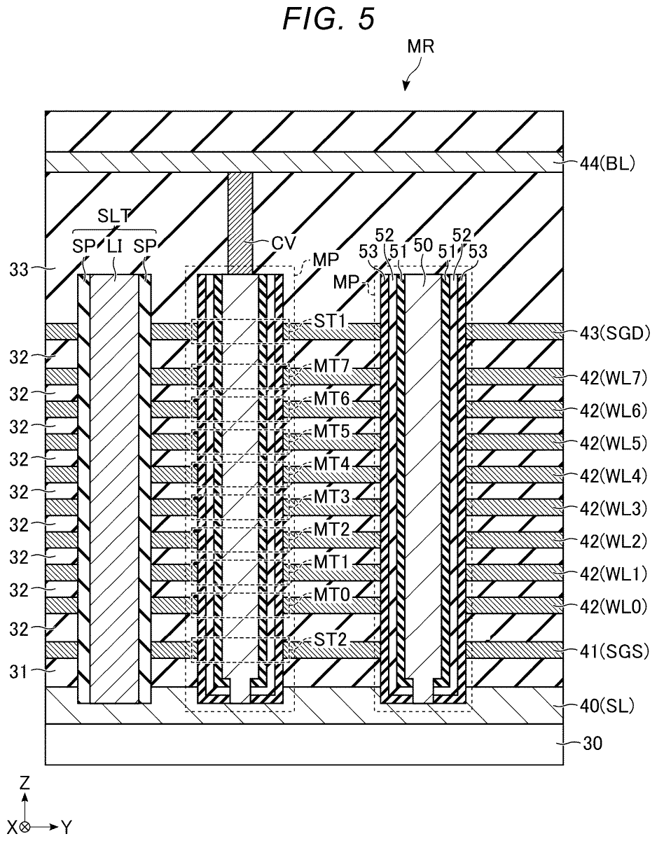

Referring to FIG. 5, an example of a cross-sectional structure of the memory region MR in the memory cell array 11 of the semiconductor memory device 10 according to the first embodiment will be described. FIG. 5 is a diagram showing the cross-sectional structure of the memory region MR in the memory cell array 11 of the semiconductor memory device 10. FIG. 5 shows a cross section including the memory pillar MP and the slit SLT and extending along the Y direction.

The memory region MR includes a semiconductor substrate 30, insulating layers 31 to 33, conductive layers 40 to 44, the memory pillar MP, the contact CV, and the slit SLT.

The conductive layer 40 is provided on the semiconductor substrate 30. The conductive layer 40 is formed, for example, in a plate shape extending along the XY plane and is used as the source line SL. For example, the conductive layer 40 contains polysilicon doped with phosphorus.

The insulating layer 31 is provided on the conductive layer 40. The conductive layer 41 is provided on the insulating layer 31. The conductive layer 41 is formed, for example, in a plate shape extending along the XY plane and is used as the select gate line SGS. For example, the conductive layer 41 contains tungsten or polysilicon doped with phosphorus. The select gate line SGS may be configured with a plurality of conductive layers 41. When the select gate line SGS is configured with the plurality of conductive layers 41, the plurality of conductive layers 41 may be configured with conductors different from each other.

The insulating layer 32 and the conductive layer 42 are alternately stacked on the conductive layer 41. Each of the plurality of conductive layers 42 is formed, for example, in a plate shape extending along the XY plane. The plurality of conductive layers 42 are used as the word lines WL0 to WL7, respectively, in order from a side of the conductive layer 40. For example, the conductive layer 42 contains tungsten. For example, the insulating layer 32 is an oxide layer containing silicon oxide (SiO₂).

The conductive layer 43 is provided on an uppermost insulating layer 32. The conductive layer 43 is formed, for example, in a plate shape extending along the XY plane and is used as the select gate line SGD. The select gate line SGD may be configured with a plurality of conductive layers 43. For example, the conductive layer 43 contains tungsten.

The insulating layer 33 is provided on the conductive layer 43. A conductive layer 44 is provided on the insulating layer 33. The conductive layer 44 is formed, for example, in a line shape extending in the Y direction and is used as the bit line BL. In a region (not shown), a plurality of conductive layers 44 are arranged in the X direction. For example, the conductive layer 44 contains copper.

Each memory pillar MP extends along the Z direction. Each memory pillar MP penetrates the insulating layers 31 and 32 and the conductive layers 41 to 43. A lower portion of the memory pillar MP is in contact with the conductive layer 40. An upper portion of the memory pillar MP reaches the insulating layer 33.

Each memory pillar MP includes, for example, a semiconductor layer 50, a tunnel insulating layer (also referred to as a tunnel insulating film) 51, a charge storage layer (for example, an insulating layer) 52, and a block insulating layer 53.

The semiconductor layer 50 extends along the Z direction. For example, a lower end of the semiconductor layer 50 is in contact with the conductive layer 40. An upper end of the semiconductor layer 50 is provided in a layer that includes the insulating layer 33. The tunnel insulating layer 51 is disposed on a side surface of the semiconductor layer 50. The charge storage layer 52 is disposed on a side surface of the tunnel insulating layer 51. The block insulating layer 53 is disposed on a side surface of the charge storage layer 52. The memory pillar MP may have a structure in which a core insulating layer is provided inside the semiconductor layer 50.

The portion where the memory pillar MP and the conductive layer 41 (that is, the select gate line SGS) intersect each other functions as the select transistor ST2. Portions where the memory pillar MP and the plurality of conductive layers 42 (that is, the word lines WL) intersect each other function as the memory cell transistors MT0 to MT7, respectively. The portion where the memory pillar MP and the conductive layer 43 (that is, the select gate line SGD) intersect each other functions as the select transistor ST1.

The semiconductor layer 50 functions as a channel layer of each of the memory cell transistors MT0 to MT7 and the select transistors ST1 and ST2. A current path of the NAND string NS is formed inside the semiconductor layer 50. The charge storage layer 52 functions as a layer storing charges of the memory cell transistor MT.

A columnar contact CV is provided on the semiconductor layer 50 of each memory pillar MP. The contact CV corresponding to one of the two memory pillars MP is shown in the region shown in the drawing. The contact CV is connected to the memory pillar MP, to which the contact CV is not connected in the region, in a region which is not shown in the drawing. One conductive layer 44 (that is, bit line BL) is in contact with the contact CV.

The slit SLT includes, for example, a spacer SP and a contact LI. The slit SLT is formed in a plate shape with at least a part thereof extending along the XZ plane, and divides the insulating layers 31 and 32 and the conductive layers 41 to 43. A lower end of the slit SLT is in contact with, for example, the conductive layer 40. An upper end of the slit SLT is provided in a layer that includes the insulating layer 33. In the slit SLT, at least a part of the contact LI extends in the X direction. The spacer SP is provided on a side surface of the contact LI. The contact LI and the plurality of conductive layers 41 to 43 are separated and insulated from each other by spacer SP.

Next, a cross-sectional structure of the memory pillar MP provided in the memory region MR will be described. FIG. 5 shows a cross section taken along line V-V in FIG. 4, and shows a cross section of the memory pillar MP in a layer parallel to a surface of the semiconductor substrate 30 and including the conductive layer 42.

The memory pillar MP has, as described above, for example, the semiconductor layer 50, the tunnel insulating layer 51, the charge storage layer 52, and the block insulating layer 53. Specifically, the semiconductor layer 50 is provided, for example, in a central portion of the memory pillar MP. The tunnel insulating layer 51 surrounds a side surface of the semiconductor layer 50. The charge storage layer 52 surrounds a side surface of the tunnel insulating layer 51. The block insulating layer 53 surrounds a side surface of the charge storage layer 52. The conductive layer 42 surrounds a side surface of the block insulating layer 53. The memory pillar MP may have a structure in which a core insulating layer is provided inside the semiconductor layer 50.

The tunnel insulating layer 51 functions as a potential barrier when charges are injected from the semiconductor layer 50 to the charge storage layer 52 or when the charges stored in the charge storage layer 52 diffuse to the semiconductor layer 50. For example, the tunnel insulating layer 51 contains silicon oxide (SiO₂).

The charge storage layer 52 has a function of storing charges injected from the semiconductor layer 50 in the memory cell transistors MT0 to MT7. For example, the charge storage layer 52 contains silicon nitride (SiN).

The block insulating layer 53 prevents the charges stored in the charge storage layer 52 from diffusing to the conductive layer 42 (word line WL). For example, the block insulating layer 53 includes an aluminum oxide layer, a silicon oxide layer, and a silicon nitride layer.

### 1.3. Operation of Semiconductor Memory Device

A read operation in the semiconductor memory device 10 of the first embodiment will be described. As described above, the read operation is performed in page units in one cell unit CU. When the TLC method capable of storing 3-bit data in the memory cell transistor MT is applied, the read operation is performed for the memory cell transistors MT connected to one word line WL for each lower page, middle page, and upper page. Here, the read operation of the lower page among the read operations of the lower page, the middle page, and the upper page will be described as an example.

In addition, the plurality of stacked word lines are referred to as WL0, WL1, WL2, . . . , WLk-1, and WLk. The word line, which is a read target, is set as a select word line WLs, two non-read target (or non-select) word lines, which are an upper layer and a lower layer adjacent to the select word line WLs, are set as adjacent word lines WLs±1, and the non-read target word lines other than the adjacent word lines WLs±1 are set as non-select word lines WLu. k is an integer of 1 or more, s is an integer of 1 or more and less than or equal to k, and u is an integer of 0 or more and less than or equal to k.

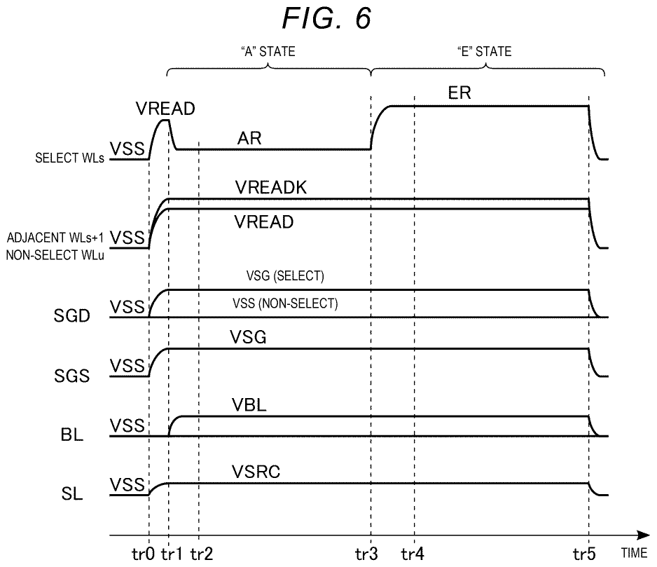

FIG. 6 is a timing chart showing the read operation of the lower page in the semiconductor memory device 10. FIG. 6 shows the voltages applied to the select word line WLs, the adjacent word lines WLs±1, the non-select word lines WLu other than the adjacent word lines, the select gate lines SGD and SGS, the bit line BL, and the source line SL in the read operation of the lower page.

First, at time tr0, the row decoder 18 applies the voltage VREAD to the select word line WLs and the non-select word line WLu. In addition, the row decoder 18 applies the voltage VREADK to the adjacent word lines WLs±1.

The voltage VREAD is a voltage that turns on the memory cell transistor MT regardless of the threshold voltage of the memory cell transistor MT, as described above, and VREAD>AR (or ER) is satisfied. The voltage VREADK is a voltage that turns on the memory cell transistor MT regardless of the threshold voltage of the memory cell transistor MT, and VREADK>VREAD is satisfied.

In addition, at time tr0, the row decoder 18 applies the voltage VSG to the select gate line SGD corresponding to the selected string unit SU, and applies, for example, the voltage VSS to the select gate line SGD corresponding to the non-select string unit SU. Furthermore, the row decoder 18 applies the voltage VSG to the selected gate line SGS. A voltage VSRC is applied to the source line SL.

The voltage VSG is a voltage that turns on the select transistors ST1 and ST2 corresponding to the selected string unit SU. Accordingly, the select transistors ST1 and ST2 of the selected string unit SU are turned on, and the select transistor ST1 of the non-select string unit SU is turned off. As a result, the remaining electrons in the channel of the NAND string NS provided in the selected string unit SU are erased.

Next, at time tr1, a read voltage AR is applied to the select word line WLs. The read voltage AR is a voltage set in accordance with the read operation of the lower page. For example, when the threshold voltage of the memory cell transistor MT, which is the read target, is higher than the read voltage AR, the memory cell transistor MT is turned off, and when the threshold voltage is equal to or lower than the read voltage AR, the memory cell transistor MT is turned on.

In addition, at time tr1, the sense amplifier 21 sets the potential of the bit line BL connected to the memory cell transistor MT, which is the read target, to the voltage VBL. Furthermore, the sense amplifier 21 sets the potential of the bit line BL connected to the memory cell transistor MT, which is the non-read target, to the voltage VSS.

Next, at time tr2, after the voltage of each of the above-described wirings is stabilized, the sense amplifier 21 senses the potential of the bit line BL connected to the memory cell transistor MT, which is the read target, and stores the sense result.

Next, at time tr3, the row decoder 18 applies the read voltage ER to the select word line WLs, applies the voltage VREADK to the adjacent word lines WLs±1, and applies the voltage VREAD to the non-select word lines WLu, respectively.

The read voltage ER is a voltage set in accordance with the read operation of the lower page, and VREADK>VREAD>ER is satisfied. For example, when the threshold voltage of the memory cell transistor MT, which is the read target, is higher than the read voltage ER, the memory cell transistor MT is turned off, and when the threshold voltage is equal to or lower than the read voltage ER, the memory cell transistor MT is turned on.

Next, at time tr4, after the voltage of each of the above-described wirings is stabilized, the sense amplifier 21 senses the potential of the bit line BL connected to the memory cell transistor MT, which is the read target, and stores the sense result.

Based on the sense result sensed by using the read voltages AR and ER described above, the data of the memory cell transistor MT connected to the select word line WLs is determined, and the lower page data is stored in the data register 20.

After that, at time tr5, the row decoder 18 applies the voltage VSS to the select word line WLs, the adjacent word lines WLs±1, the non-select word line WLu, the select gate line SGD corresponding to the select string unit and the non-select string unit, and the select gate line SGS. In addition, the sense amplifier 21 applies the voltage VSS to the bit line BL. As described above, the read operation of the lower page ends.

As described above, in the read operation, the read voltages AR and ER are applied to the select word line WLs, the voltage VREADK is applied to the adjacent word lines WLs±1, and the voltage VREAD is further applied to the non-select word line WLu. For example, one word line corresponds to the select word line WLs, and two word lines correspond to the adjacent word lines WLs±1. Furthermore, several hundreds of word lines correspond to the non-select word line WLu. As described above, the number of non-select word lines WLu to be boosted to the voltage VREAD is much larger than the number of adjacent word lines WLs±1 and the number of select word lines WLs. Therefore, during the read operation, the current amount supplied to the non-select word line WLu is much larger as compared with the current amount supplied to the adjacent word lines WLs±1 and the select word line WLs.

### 1.3.1. Configuration of Word Line Voltage Supply Circuit

Next, the word line voltage supply circuit that supplies the read voltage AR, the voltage VREADK, and the voltage VREAD to the word line WL in the read operation of the first embodiment will be described. Here, reading using the read voltage AR will be described as an example. Even in a case of reading using the read voltage ER and the other read voltages, the supply of the voltage VREADK and the voltage VREAD is the same as in the case of reading using the read voltage AR.

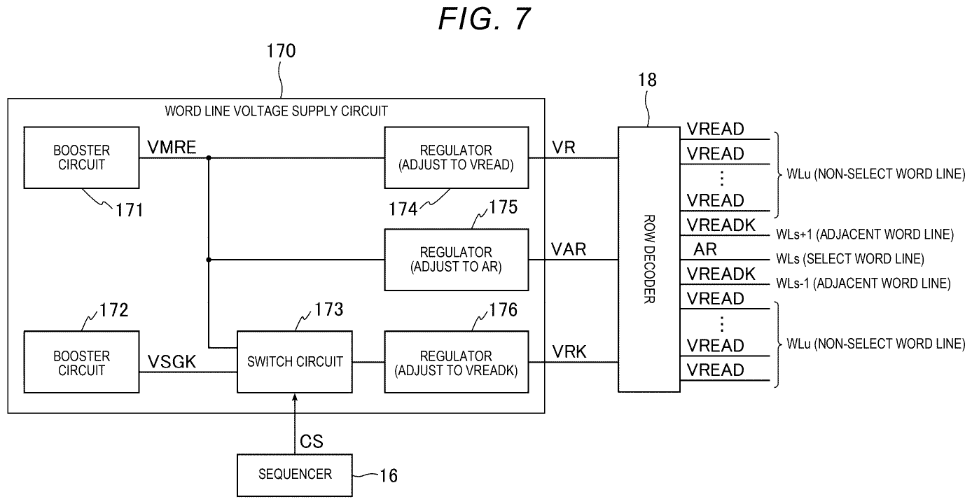

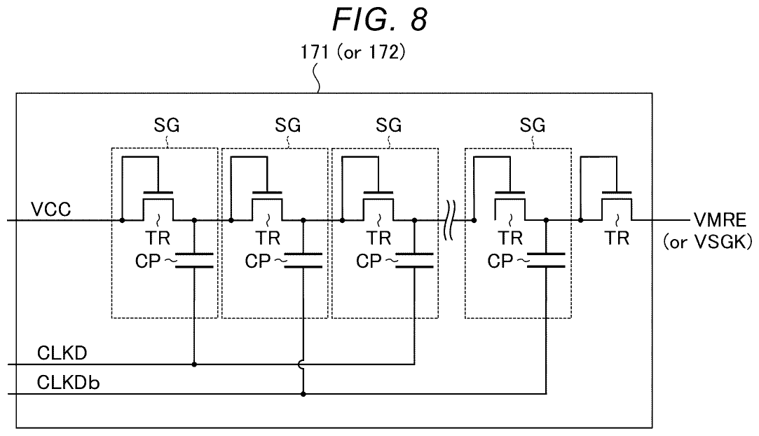

FIG. 7 is a block diagram showing a configuration of a word line voltage supply circuit 170 in the semiconductor memory device 10 of the first embodiment. FIG. 7 shows a circuit configuration for supplying the read voltage AR, the voltage VREADK, and the voltage VREAD to the word line WL in the read operation. FIG. 8 is a circuit diagram showing an example of a basic configuration of a charge pump provided in the booster circuit of the word line voltage supply circuit 170.

As shown in FIG. 7, the word line voltage supply circuit 170 includes booster circuits 171 and 172, a switch circuit 173, regulators 174, 175, and 176. The booster circuits 171 and 172, the switch circuit 173, and the regulators 174, 175, and 176 are controlled by the sequencer 16.

The booster circuit (or voltage generation circuit) 171 is a circuit that boosts an input voltage and generates a voltage VMRE. The booster circuit 171 boosts the voltage VMRE, for example, to a target voltage VMREt which is three times the voltage VCC. The booster circuit 171, having a high current supply capacity, supplies a current capable of charging the non-select word line WLu having a large load to the voltage VREAD. Here, the voltage VMRE indicates a changing voltage and is a voltage that is boosted from an offset voltage Vo to the target voltage VMREt. The target voltage VMREt is a voltage (for example, 3× voltage VCC) that is reached by being boosted by the booster circuit 171.

The booster circuit (or voltage generation circuit) 172 is a circuit that boosts an input voltage and generates a voltage VSGK higher than the voltage VMRE. The booster circuit 172 boosts the voltage VSGK, for example, to a target voltage VSGKt, which is five times the voltage VCC. The booster circuit 172, having a lower current supply capacity than the booster circuit 171, supplies a current capable of charging the adjacent word lines WLs±1, which have a small load, to a voltage VREADK higher than the voltage VREAD. Here, the voltage VSGK indicates a changing voltage and is a voltage that is boosted from the offset voltage Vo to the target voltage VSGKt. The target voltage VSGKt is a voltage (for example, 5× the voltage VCC) that is reached by being boosted by the booster circuit 172.

Each of the booster circuits 171 and 172 includes, for example, a charge pump. The charge pump includes, for example, as shown FIG. 8, a plurality of n-type MOS field effect transistors TR and a plurality of capacitors CP. In the charge pump, one stage SG is formed by the nMOS transistor TR and the capacitor CP, and a plurality of stages SG are connected. The voltage VCC, a clock signal CLKD, and a clock signal CLKDb which is an inverted signal of the clock signal CLKD are input to the charge pump. In each charge pump, the number of stages SG to be connected is different depending on the target voltage to be boosted, and the voltage VMRE or VSGK is generated.

The switch circuit 173 receives the voltage VMRE and the voltage VSGK, and outputs one of the voltage VMRE and the voltage VSGK. That is, the switch circuit 173 receives the voltage VMRE and the voltage VSGK, and selects one of the voltage VMRE and the voltage VSGK and outputs the selected voltage in response to (or based on) the control signal CS from the sequencer 16.

The regulator 174 receives the voltage VMRE, adjusts the voltage of the voltage VMRE, and outputs the voltage VR. The voltage VR changes from the offset voltage Vo to the voltage VREAD as the voltage VMRE changes from the offset voltage Vo to the target voltage VMREt. The regulator 174 outputs the voltage VREAD as the voltage VR when the voltage VMRE reaches approximately the target voltage VMREt.

The regulator 175 receives the voltage VMRE, adjusts the voltage of the voltage VMRE, and outputs the voltage VAR. The voltage VAR changes from the offset voltage Vo to the voltage AR as the voltage VMRE changes from the offset voltage Vo to the target voltage VMREt. The regulator 175 outputs the voltage AR as the voltage VAR when the voltage VMRE reaches approximately the target voltage VMREt. The regulator 175 outputs the read voltage AR using the voltage VMRE supplied from the booster circuit 171, but may output the read voltage AR using a voltage supplied from another booster circuit.

The regulator 176 receives the voltage VMRE and the voltage VSGK, adjusts the voltage of the voltage VMRE and the voltage VSGK, and outputs the voltage VRK. The voltage VRK changes from the offset voltage Vo to the vicinity of the target voltage VMREt as the voltage VMRE changes from the offset voltage Vo to the target voltage VMREt. The voltage VRK changes from the vicinity of the target voltage VMREt to the voltage VREADK when the voltage VSGK is further supplied to the regulator 176. The regulator 176 outputs the voltage VREADK as the voltage VRK when the voltage VSGK reaches approximately the target voltage VSGKt.

The row decoder 18 receives the voltage VREAD, the read voltage AR, and the voltage VREADK output from each of the regulators 174 to 176. The row decoder 18 supplies the received voltage VREAD, the read voltage AR, and the voltage VREADK to the word lines selected in accordance with a row address, respectively.

### 1.3.2. Operation of Word Line Voltage Supply Circuit

Next, an operation of the word line voltage supply circuit 170 in the read operation of the first embodiment will be described. Here, in the read operation, the voltage VREADK and the voltage VREAD supplied to the adjacent word lines WLs±1 and the non-select word line WLu will be described.

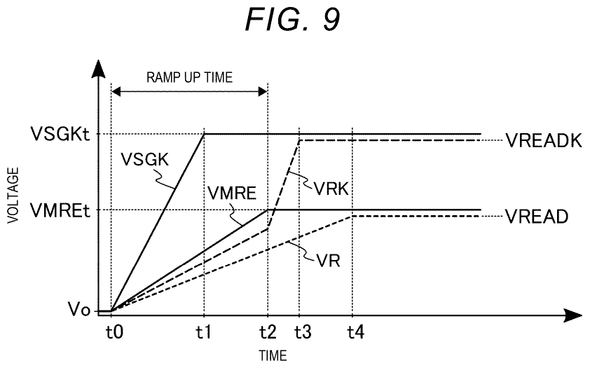

FIG. 9 is a diagram showing voltages of the booster circuits 171 and 172 and the word line WL in the read operation. As described above, in FIG. 9, the voltage VMRE is a voltage output from the booster circuit 171 and indicates a voltage of an output terminal of the booster circuit 171. The voltage VSGK is a voltage output from the booster circuit 172 and indicates a voltage of an output terminal of the booster circuit 172. The target voltage VMREt is a voltage that is reached when the voltage VMRE is boosted. The target voltage VSGKt is a voltage that is reached when the voltage VSGK is boosted.

The voltage VR indicates a voltage output from the regulator 174, that is, a voltage of an output terminal of the regulator 174. The voltage VR also indicates a voltage of the non-select word line WLu. The voltage VRK indicates a voltage output from the regulator 176, that is, a voltage of an output terminal of the regulator 176. The voltage VRK also indicates a voltage of the adjacent word lines WLs±1.

First, an outline of an operation in which the word line voltage supply circuit 170 supplies the voltage VREADK and the voltage VREAD to the adjacent word lines WLs±1 and the non-select word line WLu will be described.

The voltage of the non-select word line WLu is boosted to the voltage VREAD by the voltage VMRE output from the booster circuit 171.

The voltage of the adjacent word lines WLs±1 is boosted by the voltage VMRE until the voltage VMRE of the booster circuit 171 reaches the voltage VREt (3× VCC). Immediately after the voltage VMRE of the booster circuit 171 reaches the voltage VREt (or after reaching the voltage VREt), the output of the switch circuit 173 is switched from the voltage VMRE to the voltage VSGK output from the booster circuit 172. Accordingly, the voltage supply to the adjacent word lines WLs±1 is switched from the voltage VMRE to the voltage VSGK. Thereafter, the voltage of the adjacent word lines WLs±1 is boosted to the voltage VREADK by the voltage VSGK of the booster circuit 172.

In the following, the operation will be described in detail with reference to FIG. 9.

First, at time t0, the booster circuit 171 starts boosting the voltage VMRE. That is, the voltage VMRE is boosted by the booster circuit 171 and rises from the offset voltage Vo. The regulator 174 receives the voltage VMRE, adjusts the voltage of the voltage VMRE, and outputs the voltage VR. The voltage VR is supplied to the non-select word line WLu via the row decoder 18 and raises the voltage of the non-select word line WLu.

In addition, at time t0, the booster circuit 172 starts boosting the voltage VSGK. That is, the voltage VSGK is boosted by the booster circuit 172 and rises from the offset voltage Vo.

The switch circuit 173 receives the voltage VMRE and the voltage VSGK. The switch circuit 173 selects the voltage VMRE in response to the control signal CS from the sequencer 16 and outputs the voltage VMRE to the regulator 176. The regulator 176 receives the voltage VMRE and adjusts the voltage of the voltage VMRE to output the voltage VRK. The voltage VRK is supplied to the adjacent word lines WLs±1 via the row decoder 18 and raises the voltage of the adjacent word lines WLs±1.

Next, at time t1, the voltage VSGK is boosted by the booster circuit 172 and reaches the target voltage VSGKt (for example, 5× VCC).

At time t0 to time t2, the non-select word line WLu and the adjacent word line WLs±1 both rise by the adjusted voltages VR and VRK using the voltage VMRE output from the booster circuit 171. At this time, since the number of non-select word lines WLu is larger and the load is larger than the number of adjacent word lines WLs±1, the voltage of the non-select word line WLu (that is, the voltage VR) has a smaller slope of increase than the slope of the voltage (that is, the voltage VRK) of the adjacent word lines WLs±1. Here, a case where the slope of increase differs between the voltage of the non-select word line WLu and the voltage of the adjacent word lines WLs±1 is shown, but there may be no difference in the slope of increase and is controlled to have the same slope.

Next, at time t2, the voltage VMRE is boosted by the booster circuit 171 and reaches the target voltage VMREt (for example, 3× VCC). Hereinafter, a time from time t0 to time t2, that is, a time during which the voltage VMRE is boosted by the booster circuit 171 and reaches the target voltage VMREt from the voltage Vo is referred to as a ramp up time.

In addition, at time t2, immediately after the lapse of the ramp up time or after the lapse of the ramp up time, the switch circuit 173 selects the voltage VSGK from the voltage VMRE and the voltage VSGK and outputs the voltage VSGK to the regulator 176 in response to the control signal CS from the sequencer 16. That is, the switch circuit 173 switches the output from the voltage VMRE to the voltage VSGK, based on the control signal CS. The regulator 176 receives the voltage VSGK, adjusts the voltage of the voltage VSGK, and outputs the voltage VRK. Accordingly, the rise of the voltage VRK is steepened. The voltage VRK is supplied to the adjacent word lines WLs±1 via the row decoder 18 and further raises the voltage of the adjacent word lines WLs±1.

Next, at time t3, the voltage VRK of an output terminal of the regulator 176, that is, the voltage of the adjacent word lines WLs±1 reaches the voltage VREADK (for example, 6.4 V). Accordingly, the charging of the adjacent word lines WLs±1 to the voltage VREADK ends.

Next, at time t4, the voltage VR of the output terminal of the regulator 174, that is, the voltage of the non-select word line WLu reaches the voltage VREAD (for example, 5.7 V). Accordingly, the charging of the non-select word line WLu to the voltage VREAD ends. Thereafter, reading is executed using these word lines WL.

### 1.3. Effects According to First Embodiment

According to the first embodiment, a semiconductor memory device that can improve the reliability of the operation can be provided.

For example, in the read operation in the semiconductor memory device, the read voltage VCGRV is applied to the select word line, the voltage VREADK is applied to the adjacent word line, and the voltage VREAD is applied to the non-select word line. For example, one word line corresponds to the select word line, two word lines correspond to the adjacent word line, and several hundred word lines correspond to the non-select word line. Therefore, in the read operation, the current at the time of the boosting (or at the time of charging) the non-select word line may increase, and it may be difficult to reduce the peak current.

Therefore, in the first embodiment, the control is performed in the read operation as follows.

The voltage of the non-select word line WLu is boosted to the voltage VREAD by the voltage VMRE output from the booster circuit 171. The voltage of the adjacent word lines WLs±1 is boosted by the voltage VMRE until the “ramp up time” shown in FIG. 9 elapses, that is, until the voltage VMRE of the booster circuit 171 reaches the target voltage VMREt (3× VCC).

After the voltage VMRE of the booster circuit 171 reaches the target voltage VMREt, the voltage supply to the adjacent word line WLs±1 is switched from the voltage VMRE to the voltage VSGK of the booster circuit 172. Thereafter, the voltage of the adjacent word lines WLs±1 is boosted to the voltage VREADK by the voltage VSGK of the booster circuit 172.

In this way, the non-select word line WLu with a large load is boosted by the voltage VMRE output from the booster circuit 171. Furthermore, the adjacent word lines WLs±1 are boosted by the voltage VMRE of the booster circuit 171 until a “ramp up time” elapses, and after the “ramp up time” elapses, the voltage is switched from the voltage VMRE of the booster circuit 171 to the voltage VSGK of the booster circuit 172 and boosted by the voltage VSGK, so that the voltage VREADK, which is the final voltage of the adjacent word lines WLs±1, can be set to a voltage higher than the voltage VMRE (3× VCC). That is, the voltage VMRE of the booster circuit 171 that boosts the non-select word line WLu with a large load can be generated only by a triple boost (3× VCC). In general, the current and power efficiency of the booster circuit are higher in triple boost than in quintuple boost (5× VCC). As a result, the peak current occurring in the voltage generation circuit 17 including the word line voltage supply circuit 170 can be reduced, and the occurrence of a problem such as overheating or damage of the circuit due to the peak current can be prevented.

In addition, at the start of the voltage supply in the read operation, the voltage of the select word line WLs is boosted to the voltage VREAD, and the voltage of the adjacent word lines WLs±1 is boosted to the voltage VREADK. In the first embodiment, the voltage of the select word line WLs is boosted to the same voltage VREAD as the non-select word line WLu. The voltage of the adjacent word lines WLs±1 is boosted by the voltage VMRE output from the booster circuit 171 until the voltage VMRE of the booster circuit 171 for supplying the voltage VREAD reaches the target voltage VMREt (>VREAD). Therefore, a voltage difference generated between the select word line WLs and the adjacent word line WLs±1 can be reduced while the voltage VMRE is boosted to the target voltage VMREt. Accordingly, the influence of hot carrier injection (HCl) occurring in the memory cell transistor connected to the adjacent word lines WLs±1 can be prevented. That is, it is possible to prevent the electron from entering the charge storage layer of the memory cell transistor connected to the adjacent word lines WLs±1 and the threshold voltage of the memory cell transistor from fluctuating from an expected value.

As described above, according to the semiconductor memory device of the first embodiment, the reliability of the operation can be improved.

### 2. Second Embodiment

A semiconductor memory device of a second embodiment will be described. In the second embodiment, an example will be described in which a booster circuit that is capable of switching a voltage to be supplied from the voltage VMRE1 to the voltage VMRE2 is provided, and after the boosting (or charging) of the non-select word line ends, the output of the booster circuit is switched from the voltage VMRE1 to the voltage VMRE2. The second embodiment mainly describes differences from the first embodiment. Other configurations not described in the second embodiment are similar to those of the first embodiment.

### 2.1. Operation of Semiconductor Memory Device

### 2.1.1. Configuration of Word Line Voltage Supply Circuit

In the read operation of the second embodiment, a word line voltage supply circuit that supplies the read voltage AR, the voltage VREADK, and the voltage VREAD to the word line WL will be described. Here, as in the first embodiment, reading using the read voltage AR will be described as an example.

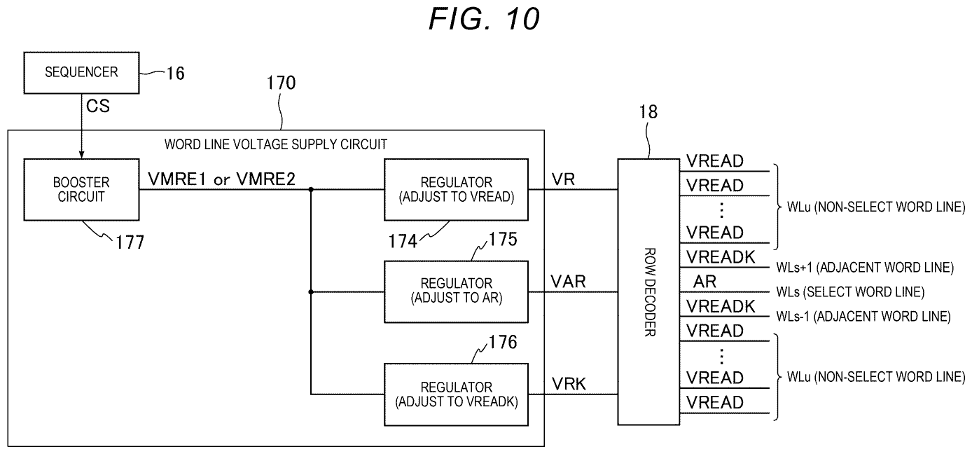

FIG. 10 is a block diagram showing a configuration of a word line voltage supply circuit 170 in the semiconductor memory device 10 of the second embodiment. FIG. 10 shows a circuit configuration for supplying the read voltage AR, the voltage VREADK, and the voltage VREAD to the word line WL in the read operation.

As shown in FIG. 10, the word line voltage supply circuit 170 includes a booster circuit 177, and regulators 174, 175, and 176. The booster circuit 177, the regulators 174, 175, and 176 are controlled by the sequencer 16.

The booster circuit (or voltage generation circuit) 177 is a circuit that boosts an input voltage and generates a voltage VMRE1 and a voltage VMRE2. The booster circuit 177 boosts the voltage VMRE1, for example, to a target voltage VMRE1t which is three times the voltage VCC. The booster circuit 177 also boosts the voltage VMRE2 to a target voltage VMRE2t that is five times the voltage VCC. Here, the voltage VMRE1 indicates a changing voltage and is a voltage that is boosted from an offset voltage Vo to the target voltage VMRE1t. The target voltage VMRE1t is a voltage (for example, 3× voltage VCC) that is reached by being boosted by the booster circuit 177. The voltage VMRE2 indicates a changing voltage and is a voltage that is boosted from the target voltage VMRE1t to a target voltage VMRE2t. The target voltage VMRE2t is a voltage (for example, 5× voltage VCC) that is reached by being boosted by the booster circuit 177. The booster circuit 177 includes, for example, the charge pump as in the first embodiment.

The regulator 174 receives the voltage VMRE1 or the voltage VMRE2, adjusts these voltages, and outputs the voltage VR. The voltage VR changes from the offset voltage Vo to the voltage VREAD as the voltage VMRE1 changes from the offset voltage Vo to the target voltage VMRE1t. The regulator 174 outputs the voltage VREAD as the voltage VR when the voltage VMRE1 reaches approximately the target voltage VMRE1t.

The regulator 175 receives the voltage VMRE1 or the voltage VMRE2, adjusts these voltages, and outputs the voltage VAR. The voltage VAR changes from the offset voltage Vo to the voltage AR as the voltage VMRE1 changes from the offset voltage Vo to the target voltage VMRE1t. The regulator 175 outputs the voltage AR as the voltage VAR when the voltage VMRE1 reaches approximately the target voltage VMRE1t. The regulator 175 outputs the read voltage AR using the voltage VMRE1 supplied from the booster circuit 171, but may output the read voltage AR using a voltage supplied from another booster circuit.

The regulator 176 receives the voltage VMRE1 or the voltage VMRE2, adjusts these voltages, and outputs the voltage VRK. The voltage VRK changes from the offset voltage Vo to the vicinity of the target voltage VMRE1t as the voltage VMRE1 changes from the offset voltage Vo to the target voltage VMRE1t. The voltage VRK changes from the vicinity of the target voltage VMRE1t to the voltage VREADK when the voltage VMRE2 is further supplied to the regulator 176. The regulator 176 outputs the voltage VREADK as the voltage VRK when the voltage VMRE2 reaches approximately the target voltage VMRE2t.

The row decoder 18 receives the voltage VREAD, the read voltage AR, and the voltage VREADK output from each of the regulators 174 to 176. The row decoder 18 supplies the received voltage VREAD, the read voltage AR, and the voltage VREADK to the word lines selected in accordance with a row address, respectively.

### 2.1.2. Operation of Word Line Voltage Supply Circuit

Next, an operation of the word line voltage supply circuit 170 in the read operation of the second embodiment will be described. In the read operation, the voltage VREADK and the voltage VREAD supplied to the adjacent word lines WLs±1 and the non-select word line WLu will be described.

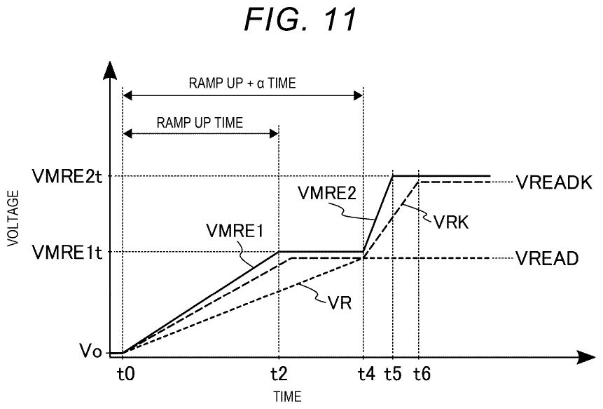

FIG. 11 is a diagram showing voltages of the booster circuit 177 and the word line WL in the read operation. As described above, in FIG. 11, the voltages VMRE1 and VMRE2 are voltages output from the booster circuit 177 and indicate a voltage of an output terminal of the booster circuit 177. The target voltage VMRE1t is a voltage that is reached when the voltage VMRE1 is boosted. The target voltage VMRE2t is a voltage that is reached when the voltage VMRE2 is boosted.

The voltage VR indicates a voltage output from the regulator 174, that is, a voltage of an output terminal of the regulator 174. The voltage VR also indicates a voltage of the non-select word line WLu. The voltage VRK indicates a voltage output from the regulator 176, that is, a voltage of an output terminal of the regulator 176. The voltage VRK also indicates a voltage of the adjacent word lines WLs±1.

First, an outline of an operation in which the word line voltage supply circuit 170 supplies the voltage VREADK and the voltage VREAD to the adjacent word lines WLs±1 and the non-select word line WLu will be described.

In the booster circuit 177, the output target voltage is controlled in two stages of the voltage VMRE1t (3× VCC) and the voltage VMRE2t (5× VCC).

The voltages of the non-select word line WLu and the adjacent word lines WLs±1 are boosted by the voltage VMRE1 output from the booster circuit 177 until the “ramp up+α time” shown in FIG. 11 elapses. That is, the voltage VMRE1 output from the booster circuit 177 reaches the target voltage VMRE1t (3× VCC) by the boosting, and then the voltages of the non-select word line WLu and the adjacent word line WLs±1 are boosted by the voltage VMRE1 output from the booster circuit 177 until the voltage of the non-select word line WLu is boosted to the voltage VREAD.

Immediately after the voltage of the non-select word line WLu is boosted to the voltage VREAD, the target voltage output from the booster circuit 177 is switched from the voltage VMRE1t (3× VCC) to the voltage VMRE2t (5× VCC). Thereafter, the voltage of the adjacent word lines WLs±1 is boosted to the voltage VREADK by the voltage VMRE2 output from the booster circuit 177.

In the following, the operation will be described in detail with reference to FIG. 11.

First, at time t0, the booster circuit 177 starts boosting the voltage VMRE1. That is, the voltage VMRE1 is boosted by the booster circuit 177 and rises from the offset voltage Vo. The regulator 174 receives the voltage VMRE1, adjusts the voltage of the voltage VMRE1, and outputs the voltage VR. The voltage VR is supplied to the non-select word line WLu via the row decoder 18 and raises the voltage of the non-select word line WLu. The regulator 176 receives the voltage VMRE1 and adjusts the voltage of the voltage VMRE1 to output the voltage VRK. The voltage VRK is supplied to the adjacent word lines WLs±1 via the row decoder 18 and raises the voltage of the adjacent word lines WLs±1.

Next, at time t2, the voltage VMRE1 is boosted by the booster circuit 177 and reaches the target voltage VMRE1t (for example, 3× VCC). Hereinafter, as in the first embodiment, a time from time t0 to time t2, that is, a time during which the voltage VMRE1 is boosted by the booster circuit 177 and reaches the target voltage VMRE1t from the voltage Vo is referred to as a ramp up time.

Next, at time t4, the voltage VR of the output terminal of the regulator 174, that is, the voltage of the non-select word line WLu reaches the voltage VREAD (for example, 5.7 V). Accordingly, the charging of the non-select word line WLu to the voltage VREAD ends. Hereinafter, a time from time t2 to time t4, that is, a time until the voltage of the non-select word line WLu is boosted to the voltage VREAD after the voltage VMRE1 reaches the target voltage VMRE1t is referred to as an α time.

At time t0 to time t4, the non-select word line WLu and the adjacent word line WLs±1 both rise by the adjusted voltages VR and VRK using the voltage VMRE1 output from the booster circuit 177. At this time, since the number of non-select word lines WLu is larger and the load is larger than the number of adjacent word lines WLs±1, the voltage of the non-select word line WLu (that is, the voltage VR) has a smaller slope of increase than the slope of the voltage (that is, the voltage VRK) of the adjacent word lines WLs±1. Here, a case where the slope of increase differs between the voltage of the non-select word line WLu and the voltage of the adjacent word lines WLs±1 is shown, but there may be no difference in the slope of increase and is controlled to have the same slope.

In addition, at time t4, immediately after the lapse of “ramp up+α time”, or after the lapse of the “ramp up+α time”, the booster circuit 177 switches the target voltage from the voltage VMRE1t to the voltage VMRE2t and switches the output from the voltage VMRE1 to the voltage VMRE2 in response to the control signal CS from the sequencer 16. The regulator 176 receives the voltage VMRE2 and adjusts the voltage of the voltage VMRE2 to output the voltage VRK. Accordingly, the rise of the voltage VRK is steepened. The voltage VRK is supplied to the adjacent word lines WLs±1 via the row decoder 18 and further raises the voltage of the adjacent word lines WLs±1.

Next, at time t5, the voltage VMRE2 is boosted by the booster circuit 177 and reaches the target voltage VMRE2t (for example, 5× VCC).

Next, at time t6, the voltage VRK of an output terminal of the regulator 176, that is, the voltage of the adjacent word lines WLs±1 reaches the voltage VREADK (for example, 6.4 V). Accordingly, the charging of the adjacent word lines WLs±1 to the voltage VREADK ends. Thereafter, reading is executed using these word lines WL.

### 2.3. Effects According to Second Embodiment

According to the second embodiment, as in the first embodiment, the semiconductor memory device that can improve the reliability of the operation can be provided.

In the second embodiment, the control is performed in the read operation as follows.

In the booster circuit 177, the output target voltage is controlled in two stages of the voltage VMRE1t (3× VCC) and the voltage VMRE2t (5× VCC).

The voltages of the non-select word line WLu and the adjacent word lines WLs±1 are boosted by the voltage VMRE1 output from the booster circuit 177 until the “ramp up+α time” shown in FIG. 11 elapses. That is, the voltages of the non-select word line WLu and the adjacent word line WLs±1 are boosted by the voltage VMRE1 until the voltage VMRE1 output from the booster circuit 177 reaches the target voltage VMRE1t (3× VCC) by the boosting, and then the voltage of the non-select word line WLu is boosted to the voltage VREAD.

After the voltage of the non-select word line WLu is boosted (or charged) to the voltage VREAD, the target voltage of the booster circuit 177 is switched from the voltage VMRE1t (3× VCC) to the voltage VMRE2t (5× VCC). Thereafter, the voltage of the adjacent word lines WLs±1 is boosted to the voltage VREADK by the voltage VMRE2 output from the booster circuit 177.

In this way, the non-select word line WLu with a large load is boosted by the voltage VMRE1 output from the booster circuit 177. Furthermore, the adjacent word lines WLs±1 is boosted by the voltage VMRE1 of the booster circuit 177 until the “ramp up+α time” elapses, and after the “ramp up+α time” elapses, the voltage VMRE1 of the booster circuit 177 is switched to the voltage VMRE2 and boosted by the voltage VMRE2, so that the voltage VREADK, which is the final voltage of the adjacent word lines WLs±1, can be set to a voltage higher than the voltage VMRE1 (3× VCC). That is, the voltage VMRE1 of the booster circuit 177 that boosts the non-select word line WLu with a large load can be generated only by a triple boost (3× VCC). In general, the current and power efficiency of the booster circuit are higher in triple boost than in quintuple boost (5× VCC). As a result, when switching from the target voltage VMRE1t to the target voltage VMRE2t, the peak current occurring in the voltage generation circuit 17 including the word line voltage supply circuit 170 can be reduced, and the occurrence of a problem such as overheating or damage of the circuit due to the peak current can be prevented.

In addition, at the start of the voltage supply in the read operation, the voltage of the select word line WLs is boosted to the voltage VREAD, and the voltage of the adjacent word lines WLs±1 is boosted to the voltage VREADK. In the second embodiment, the voltage of the select word line WLs is boosted to the same voltage VREAD as the non-select word line WLu. The voltage of the adjacent word lines WLs±1 is boosted by the voltage VMRE1 for supplying the voltage VREAD, which is output from the booster circuit 177, until the voltage of the non-select word line WLu is boosted to the voltage VREAD. Therefore, a voltage difference generated between the select word line WLs and the adjacent word line WLs±1 can be reduced while the voltage of the non-select word line WLu is boosted to the voltage VREAD. Accordingly, the influence of hot carrier injection (HCI) occurring in the memory cell transistor connected to the adjacent word lines WLs±1 can be prevented. That is, it is possible to prevent the occurrence of a problem such as the entry of the electron into the charge storage layer of the memory cell transistor connected to the adjacent word lines WLs±1 and the fluctuation of the threshold voltage of the memory cell transistor from an expected value.

As described above, according to the semiconductor memory device of the second embodiment, the reliability of the operation can be improved.

Furthermore, in the above-described embodiment, the NAND flash memory is described as an example of a semiconductor memory, but the present disclosure may be applied not only to the NAND flash memory but also to other semiconductor memories in general, and further to various storage devices other than the semiconductor memory.

In the above-described embodiment, functional blocks may be implemented as either hardware, computer software, or a combination of both. It is not essential that the functional blocks are distinguished as in the following example. For example, some functions may be executed by a functional block different from the exemplified functional block. Furthermore, the exemplified functional block may be subdivided into finer functional subblocks.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a memory cell array including a plurality of memory cells and a plurality of word lines;
a first booster circuit configured to boost an input voltage to generate a first voltage;
a second booster circuit configured to boost the input voltage to generate a second voltage higher than the first voltage;
a first regulator configured to adjust the first voltage to output a third voltage;
a second regulator configured to adjust the second voltage to output a fourth voltage;
a switch circuit configured to receive the first voltage and the second voltage and output one of the first voltage or the second voltage; and
a row decoder configured to apply a voltage to the plurality of word lines,
wherein the switch circuit is configured to switch an output from the first voltage to the second voltage in response to the first voltage being boosted to a target voltage by the first booster circuit.

2. The semiconductor memory device according to claim 1, further comprising:
a control circuit operatively coupled to the first booster circuit and the switch circuit,
wherein the control circuit is configured to output a control signal to the switch circuit when the first voltage is boosted to the target voltage by the first booster circuit, and
the switch circuit is configured to switch the output from the first voltage to the second voltage in response to the control signal.

3. The semiconductor memory device according to claim 1,
wherein in a read operation of one of the memory cells connected to a selected word line among the plurality of word lines, the row decoder is configured to:
apply the fourth voltage output from the second regulator to a word line among the plurality of word lines adjacent to the selected word line; and
apply the third voltage output from the first regulator to a non-selected word line among the plurality of word lines other than the selected word line and the adjacent word line.

4. The semiconductor memory device according to claim 1, further comprising:
a third regulator configured to adjust the first voltage to output a fifth voltage.

5. The semiconductor memory device according to claim 4,
wherein in a read operation for applying a read voltage to a selected word line among the plurality of word lines, the row decoder is configured to:
apply the fifth voltage output from the third regulator to the selected word line;
apply the fourth voltage output from the second regulator to a word line among the plurality of word lines adjacent to the selected word line; and
apply the third voltage output from the first regulator to a non-select word line among the plurality of word lines other than the selected word line and the adjacent word line.

6. The semiconductor memory device according to claim 3,
wherein the plurality of word lines extend in a first direction and are stacked in a second direction intersecting the first direction, and
the adjacent word line is disposed adjacent to the selected word line in the second direction.

7. The semiconductor memory device according to claim 4,
wherein the third voltage is higher than the fifth voltage, and the fourth voltage is higher than the third voltage.

8. The semiconductor memory device according to claim 1,
wherein each of the first booster circuit and the second booster circuit includes a charge pump.

9. The semiconductor memory device according to claim 1,
wherein the memory cell array includes a pillar,
the plurality of word lines extend in a first direction and are stacked in a second direction intersecting the first direction, and
the pillar extends in the second direction and penetrates the plurality of word lines.

10. The semiconductor memory device according to claim 1,
wherein the memory cell array includes a NAND flash memory in which the plurality of memory cells are arranged three-dimensionally.

11. A semiconductor memory device comprising:
a memory cell array including a plurality of word lines and a plurality of memory cells;
a booster circuit configured to boost an input voltage to generate a first voltage and a second voltage higher than the first voltage;
a first regulator configured to adjust one of the first voltage or the second voltage to output a third voltage;
a second regulator configured to adjust one of the first voltage or the second voltage to output a fourth voltage; and
a row decoder configured to apply a voltage to the plurality of word lines,
wherein in a read operation of one of the memory cells connected to a selected word line among the plurality of word lines,
the booster circuit is configured to switch a voltage to be generated from the first voltage to the second voltage in response to a non-select word line other than a word line adjacent to the selected word line among the plurality of word lines being boosted to the third voltage.

12. The semiconductor memory device according to claim 11, further comprising:
a control circuit operatively coupled to the booster circuit,
wherein the control circuit is configured to output a control signal to the booster circuit when the non-select word line is boosted to the third voltage, and
the booster circuit is configured to switch a voltage to be generated from the first voltage to the second voltage in response to the control signal.

13. The semiconductor memory device according to claim 11,
wherein in the read operation, the row decoder is configured to:
apply the fourth voltage output from the second regulator to a word line adjacent to the selected word line among the plurality of word lines, and
apply the third voltage output from the first regulator to a non-select word line other than the selected word line and the adjacent word line among the plurality of word lines.

14. The semiconductor memory device according to claim 11, further comprising:
a third regulator configured to adjust one of the first voltage or the second voltage to output a fifth voltage.

15. The semiconductor memory device according to claim 14,
wherein in the read operation, the row decoder is configured to:
apply the fifth voltage output from the third regulator to the selected word line;
apply the fourth voltage output from the second regulator to a word line adjacent to the selected word line among the plurality of word lines; and
apply the third voltage output from the first regulator to a non-select word line other than the selected word line and the adjacent word line among the plurality of word lines.

16. The semiconductor memory device according to claim 13,
wherein the plurality of word lines extend in a first direction and are stacked in a second direction intersecting the first direction, and
the adjacent word line is disposed adjacent to the selected word line in the second direction.

17. The semiconductor memory device according to claim 14,
wherein the third voltage is higher than the fifth voltage, and the fourth voltage is higher than the third voltage.

18. The semiconductor memory device according to claim 11,
wherein the booster circuit includes a charge pump.

19. The semiconductor memory device according to claim 11,
wherein the memory cell array includes a pillar,
the plurality of word lines extend in a first direction and are stacked in a second direction intersecting the first direction, and
the pillar extends in the second direction and penetrates the plurality of word lines.

20. The semiconductor memory device according to claim 11,
wherein the memory cell array includes a NAND flash memory in which the plurality of memory cells are arranged three-dimensionally.
